(19) United States
(12) Patent Application Publication
(10) Pub. No.: US 2025/0206172 A1
(43) Pub. Date: Jun. 26, 2025

(54) CHARGE CONTROL DEVICE

(71) Applicant: TOYOTA JIDOSHA KABUSHIKI KAISHA, Toyota-shi (JP)

(72) Inventors: Daiki TAKATSUKA, Toyota-shi (JP); Fumiyoshi KURIBARA, Toyota-shi (JP)

(73) Assignee: TOYOTA JIDOSHA KABUSHIKI KAISHA, Toyota-shi (JP)

(21) Appl. No.: 18/795,491

(22) Filed: Aug. 6, 2024

(30) Foreign Application Priority Data
Dec. 25, 2023 (JP) 2023-218339

(51) Int. Cl. B60L 53/62; H02J 7/00

(52) U.S. Cl. CPC B60L 53/62; H02J 7/0029; H02J 7/0047

(57) ABSTRACT

The charge control device includes an ECU. ECU obtains a first voltage from the first voltmeter, a second voltage from the second voltmeter, and a third voltage from the third voltmeter. ECU diagnoses welding of the C-contact relays based on the first voltage. the second voltage, and the third voltage.

### CROSS-REFERENCE TO RELATED APPLICATION

This application claims priority to Japanese Patent Application No. 2023-218339 filed on Dec. 25, 2023, incorporated herein by reference in its entirety.

### BACKGROUND

### 1. Technical Field

The present disclosure relates to a charge control device.

### 2. Description of Related Art

Japanese Unexamined Patent Application Publication No. 2019-092310 (JP 2019-092310 A) describes a technology for performing self-diagnosis during traveling of a vehicle and detecting a failure in a vehicle charging device that charges a battery by receiving electric power supplied from the outside of the vehicle. In this technology, a failure diagnosis unit switches an alternating current (AC) input switch from a disconnected state to a connected state to input an AC voltage generated by an AC discharge unit to an alternating current-to-direct current (AC-DC) conversion unit, thereby performing failure diagnosis in an AC charge path from the AC-DC conversion unit to the battery.

### SUMMARY

In the vehicle charging device as in JP 2019-092310 A, AC and DC input paths from a charging station are the same. Therefore, it is necessary to prohibit DC charging when a contact relay between the charging station and an AC outlet is fused in a case where the C setting of the AC path is switched from the station side to the AC outlet side during the DC charging.

In JP 2019-092310 A, however, the state in which the contact relay between the charging station and the AC outlet is fused is not take into consideration. In this case, a current flows through the AC outlet during the DC charging, and a failure may occur due to unexpected application of a DC voltage to devices using AC 100 V.

The present disclosure provides a charge control device capable of detecting fusion of a contact relay between a charging station and an AC outlet.

In order to solve the above problem and achieve the above object, a charge control device according to the present disclosure is

a charge control device including a bi-directional charger, a C-contact relay configured to electrically connect the bi-directional charger to either an inlet or an alternating current outlet, and a processor.

The processor is configured to:

acquire a first voltage from a first voltmeter provided between the inlet and the C-contact relay, a second voltage from a second voltmeter provided between the C-contact relay and the bi-directional charger, and a third voltage from a third voltmeter provided between the C-contact relay and the alternating current outlet; and
diagnose fusion of the C-contact relay based on the first voltage, the second voltage, and the third voltage.

The present disclosure provides an effect that the fusion of the contact relay between the charging station and the AC outlet can be detected.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram illustrating a functional configuration of a charge control device according to an embodiment;

FIG. 2 is a flow chart illustrating an outline of the welding determination process executed by ECU according to the embodiment; and

FIG. 3 is a flow chart illustrating an outline of a charge determination process performed by ECU according to the embodiment.

### DETAILED DESCRIPTION OF EMBODIMENTS

Hereinafter, a vehicle including a charge control device according to an embodiment of the present disclosure will be described with reference to the drawings. The constituent elements in the following embodiments include those that can be easily replaced by a person skilled in the art or those that are substantially the same. In addition, the drawings referred to in the following description only schematically show shapes, sizes, and positional relationships to the extent that the contents of the present disclosure can be understood. That is, the present disclosure is not limited to only the shapes, sizes, and positional relationships illustrated in the drawings.

### Configuration of Charge Control Device

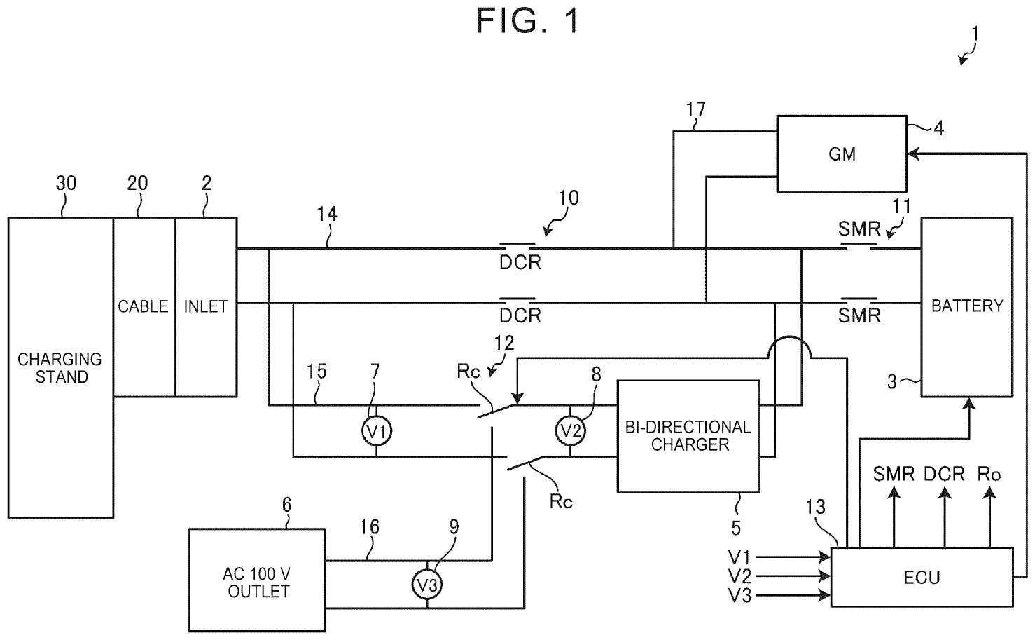

FIG. 1 is a schematic configuration diagram illustrating a functional configuration of a charge control device according to an embodiment. The charge control device 1 shown in FIG. 1 is provided in vehicles such as a hybrid electric vehicle (HEV), a plug-in hybrid electric vehicle (PHEV), and a battery electric vehicle (BEV).

As illustrated in FIG. 1, the charge control device 1 includes an inlet 2, a battery 3, a motor generator 4 (hereinafter, simply referred to as “MG 4”), a bi-directional charger 5, and an AC100 V outlet 6. The charge control device 1 further comprises a first voltmeter 7, a second voltmeter 8, a third voltmeter 9, an A-contact relay 10 (DCR), a C-contact relay 12 (Rc), an SMR relay 11 and an ECU 13.

The inlet 2 is electrically connected to the first power line 14 connected to the battery 3 via the A-contact relay 10 and SMR relay 11. The inlet 2 is electrically connected to the second power line 15 connected to the battery 3 via the C-contact relay 12, the bi-directional charger 5, and SMR relay 11. The inlet 2 is electrically connected to the charging station 30 via a cable 20, and outputs electric power supplied from the charging station 30 to the battery 3.

The battery 3 is configured using, for example, a lithium-ion secondary battery or a nickel-hydrogen secondary battery. The battery 3 is electrically connected to the first power line 14 electrically connected to the inlet 2 via the A-contact relay 10 and SMR relay 11. In addition, the battery 3 is electrically connected to a second power line 15 (DC path) connected to the inlet 2 via SMR relay 11, the bi-directional charger 5, and the C-contact relay 12. Further, the battery 3 is electrically connected to a third power line 16 (AC path) connected to AC100 V outlet 6 via SMR relay 11, the bi-directional charger 5 and the C-contact relay 12. The battery 3 is electrically connected to the fourth power line 17 to which MG 4 is connected. Battery 3 supplies electric power to MG 4 and charges electric power generated during regeneration from MG 4.

MG 4 is driven by using the electric power supplied through the fourth power line 17, and the regenerative electric power generated at the time of deceleration of the vehicle is outputted to the battery 3.

The bi-directional charger 5 is configured to be capable of bi-directionally charging. The bi-directional charger 5 is electrically connected to the battery 3 via SMR relay 11, and is electrically connected to the second power line 15 (DC path) or the third power line 16 (AC path) via the C-contact relay 12. The bi-directional charger 5 converts the DC power output from the battery 3 via the second power line 15 into a predetermined voltage and outputs the voltage to the inlet 2. Further, the bi-directional charger 5 converts the DC power output from the battery 3 via the second power line 15 into AC power, converts the voltage of the converted AC power into a predetermined voltage, and outputs the voltage to AC100 V outlet 6.

AC100 V outlet 6 is electrically connected to the third power line to which the battery 3 is connected via SMR relay 11, the bi-directional charger 5, and the C-contact relay 12. AC100 V outlet 6 supplies power to the connected external loads. In the embodiment, AC100 V outlet 6 functions as an AC outlet.

The first voltmeter 7 is provided in the second power line 15 between the inlet 2 and the C-contact relay 12. The first voltmeter 7 detects a first voltage V1 flowing through the second power line 15 and outputs the first voltage V1 to ECU 13.

The second voltmeter 8 is provided in the second power line 15 between the C-contact relay 12 and the bi-directional charger 5. The second voltmeter 8 detects a second voltage V2 flowing in the second power line 15 between the C-contact relay 12 and the bi-directional charger 5 and provides this second voltage V2 to ECU 13.

A third voltmeter 9 is provided in the third power line 16 between the C-contact relay 12 and AC100 V outlet 6. The third voltmeter 9 detects a third voltage V3 flowing in the third power line 16 between the C-contact relay 12 and AC100 V outlet 6 and provides this third voltage V3 to ECU 13.

The A-contact relay 10 is a changeover switch for conducting or disconnecting the first power line 14 from the inlet 2 to the battery 3 under the control of ECU 13. The A-contact relay 10 is configured by using a relay having a pair of contacts for conducting or blocking the positive electrode side and the negative electrode side of the first power line 14, respectively. The A-contact relay 10 is turned on when power is supplied from the inlet 2 when the vehicle is stopped under the control of ECU 13. On the other hand, the A-contact relay 10 is shut off when electric power is supplied from the battery 3 to the inlet 2 or AC100 V outlet 6 when the vehicles are traveling under the control of ECU 13.

SMR relay 11 is a changeover switch for conducting or disconnecting the first power line 14 from the inlet 2 to the battery 3 under the control of ECU 13. SMR relay 11 is configured by using a relay having a pair of contacts for conducting or blocking the positive and negative sides of the first power line 14.

The C-contact relay 12 is a changeover switch for switching to the second power line 15 from the bi-directional charger 5 to the inlet 2 or the third power line 16 from the bi-directional charger 5 to AC100 V outlet 6 under the control of ECU 13. The C-contact relay 12 is configured by using a relay having a pair of contacts for switching the positive electrode side and the negative electrode side to the inlet 2 or AC100 V outlet 6.

ECU 13 is implemented using a processor including memories and hardware. The hardware may be, for example, memories, a central processing unit (CPU), a digital signal processor (DSP) and a field-programmable gate array (FPGA). ECU 13 obtains a first voltage V1, a second voltage V2 and a third voltage V3. The first voltage V1 is obtained from a first voltmeter 7 provided between the inlet 2 and the C-contact relay 12. The second voltage V2 is obtained from a second voltmeter 8 provided between the C-contact relay 12 and the bi-directional charger 5. The third voltage V3 is obtained from a third voltmeter 9 provided between the C-contact relay 12 and AC100 V outlet 6. Then, ECU 13 diagnoses the welding of the C-contact relay 12 based on the first voltage V1, the second voltage V2, and the third voltage V3. In one embodiment, ECU 13 functions as a processor.

### Welding Determination Process

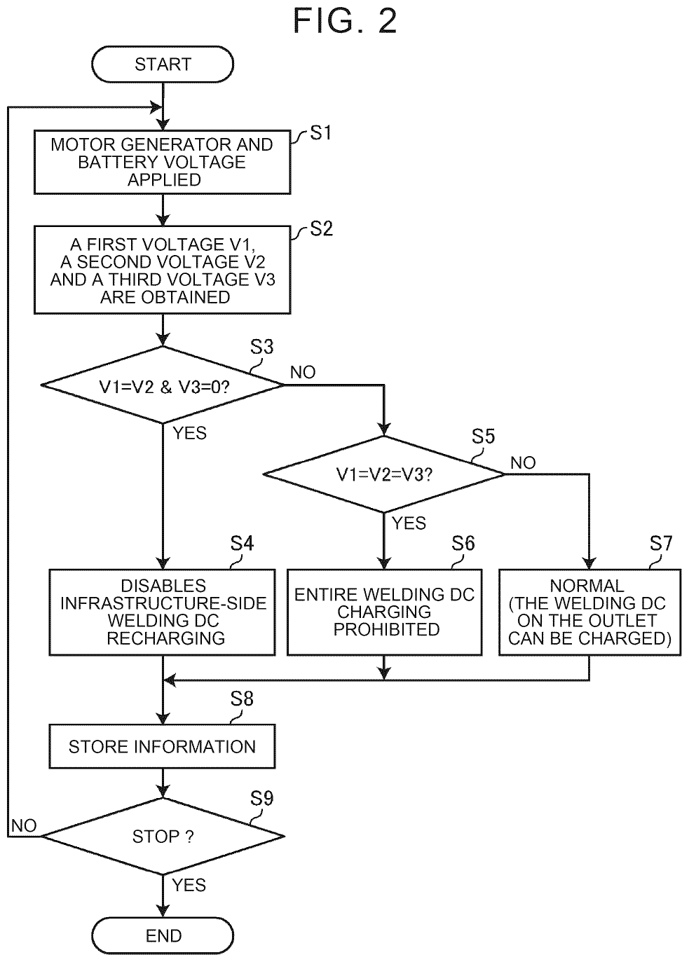

Next, the welding determination process executed by ECU 13 will be described. FIG. 2 is a flow chart illustrating an outline of the welding determination process performed by ECU 13. In FIG. 2, the welding determination process performed while the vehicles are running prior to DC charge will be described.

As shown in FIG. 2, ECU 13 is ready for AC power supply. For this reason, the C-contact relay 12 is controlled, the connection destination of the C-contact relay 12 is switched to the third power line 16 of AC100 V outlet 6, and is connected to the bi-directional charger 5 from MG 4 and the battery 3 (S1). The bi-directional charger 5 then energizes the C-contact relay 12 using power supplied from MG 4 or battery 3.

Subsequently, ECU 13 obtains a first voltage V1 from the first voltmeter, a second voltage V2 from the second voltmeter, and a third voltage V3 from the third voltmeter (S2).

Thereafter, ECU 13 determines whether the respective values (voltages) of the first voltage V1, the second voltage V2, and the third voltage V3 are 0 (V1=V2 & V3=0) (S3). When the values of the first voltage V1, the second voltage V2, and the third voltage V3 are 0 (V1=V2 & V3=0) (S3: Yes), ECU 13 proceeds to S4 described later. On the other hand, when the respective values of the first voltage V1, the second voltage V2, and the third voltage V3 are 0 (V1=V2 & V3=0) (S3: No), ECU 13 proceeds to S5 to be described later.

In S4, ECU 13 determines that welding has occurred on the infrastructure-side and prohibits DC charging. After S4, ECU 13 proceeds to S8 to be described later.

In S5, ECU 13 determines whether each of the first voltage V1, the second voltage V2, and the third voltage V3 is the same voltage (V1=V2=V3). When the values of the first voltage V1, the second voltage V2, and the third voltage V3 are the same voltage (V1=V2=V3) (S5: Yes), ECU 13 proceeds to S6 to be described later. On the other hand, when the values of the first voltage V1, the second voltage V2, and the third voltage V3 are not the same voltage (V1=V2=V3) (S5: No), ECU 13 proceeds to S7 to be described later.

In S6, it is determined that the C-contact relay 12 is fully welded, and DC charge is prohibited. After S6, ECU 13 proceeds to S8 to be described later.

In S7, ECU 13 determines that the C-contact relay 12 is welded to the third power line 16 to AC100 V outlet 6 and allows for DC charge. After S7, ECU 13 proceeds to S8 to be described later.

In S8, ECU 13 stores information regarding the status of the C-contact relay 12 determined by S4, S6 and S7, respectively.

Subsequently, ECU 13 determines whether or not the vehicle is stopped by inputting an instruction signal for stopping the driving of the vehicle from an ignition switch (not shown) (S9). When the vehicle is stopped (S9: Yes), ECU 13 ends this process. On the other hand, when the vehicles are not stopped (S9: No), ECU 13 returns to S1.

### Charge Determination Process

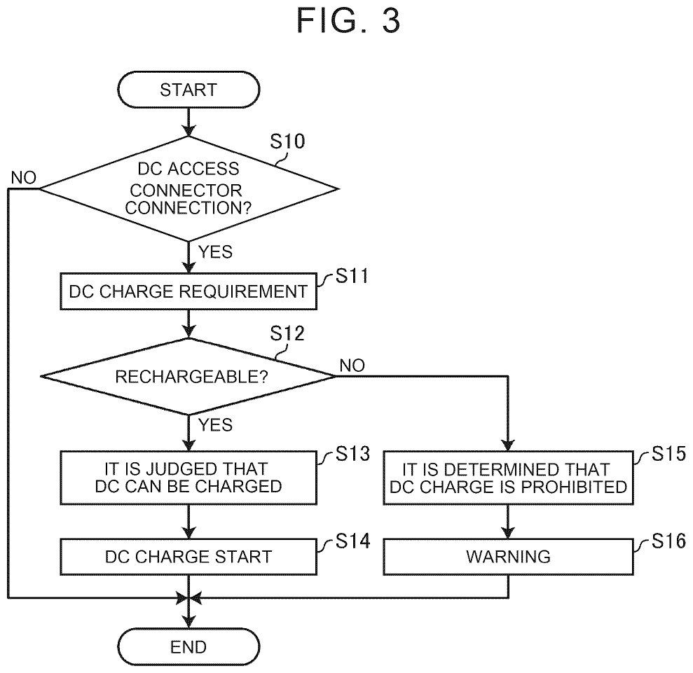

Next, a charge determination process executed by ECU 13 will be described. FIG. 3 is a flow chart illustrating an outline of a charge determination process executed by ECU 13.

As illustrated in FIG. 3, ECU 13 determines whether or not the charging station 30 is connected to the inlet 2 via the cable 20 (S10). When the charging station 30 is connected to the inlet 2 via the cable 20 (S10: Yes), ECU 13 proceeds to S11 to be described later. On the other hand, when the charging station 30 is not connected to the inlet 2 via the cable 20 (S10: No), ECU 13 ends this process.

In S11, ECU 13 requests DC charging from the charging station 30 on the basis of an instruction signal for instructing DC charging, which is inputted from a switch (not shown).

Subsequently, ECU 13 determines whether or not the C-contact relay 12 is normal based on the status of the C-contact relay 12 stored in the memories (S12). When the C-contact relay 12 is normal (S12: Yes), ECU 13 determines that DC power can be supplied from the charging station 30 (S13).

ECU 13 then S14 DC charge by making the first power line 14 conductive by controlling the A-contact relay 10 and SMR relay 11. After S14, ECU 13 ends this process.

In S12, when the C-contact relay 12 is not normal (S12: No), ECU 13 determines that DC charging from the charging station 30 is prohibited because abnormal welding has occurred in the C-contact relay 12 (S15).

Subsequently, ECU 13 outputs a warning indicating that DC power supply cannot be performed because the C-contact relay 12 is abnormally welded to a display panel of a speaker or a car navigation system (not shown) (S16). In this instance, ECU 13 may cause the car navigation system to output a message/voice. As a result, the user can recognize that an abnormality has occurred in the charging system. After S12, ECU 13 ends this process.

According to one embodiment described above, ECU 13 diagnoses welding of the C-contact relay 12 based on the first voltage V1, the second voltage V2 and the third voltage V3. Therefore, it is possible to suppress an unexpected DC voltage from being applied to AC100 V outlet 6.

In addition, according to an embodiment, ECU 13 may differ in each of the first voltage V1, the second voltage V2, and the third voltage V3. In this case, the C-contact relay 12 is determined to be normal, and is determined to be chargeable. Therefore, the state of the C-contact relay 12 can be grasped before the voltage is applied.

In addition, according to an embodiment, ECU 13 may not differ in each of the first voltage V1, the second voltage V2, and the third voltage V3. In this case, it is determined that the C-contact relay 12 is abnormal, and charging from the outside is prohibited. Therefore, it is possible to suppress an unexpected DC voltage from being applied to AC100 V outlet 6.

Further, according to an embodiment, ECU 13 may be 0 for each of the first voltage V1, the second voltage V2, and the third voltage V3. In this case, it is determined that the C-contact relay 12 is in an abnormal state welded to the infrastructure side, and charging from the outside is prohibited. Therefore, an abnormal portion of the C-contact relay 12 can be identified.

Further, according to an embodiment, ECU 13 may have the same value for each of the first voltage V1, the second voltage V2, and the third voltage V3. In this case, it is determined that the C-contact relay 12 is in an abnormal state in which all the contacts have been welded, and charging from the outside is prohibited. Therefore, an abnormal portion of the C-contact relay 12 can be identified.

Additional benefits and variations can be readily derived by one of ordinary skill in the art. The broader aspects of the disclosure are not limited to the specific details and representative embodiments presented and described above. Accordingly, various modifications may be made without departing from the spirit or scope of the general inventive concept as defined by the appended claims and their equivalents.

While some of the embodiments of the present application have been described in detail with reference to the drawings, these are merely examples, and the present disclosure can be implemented in other forms in which various modifications and improvements are made based on the knowledge of a person skilled in the art, including the aspects described in the section of the disclosure of the present disclosure.

What is claimed is:

1. A charge control device comprising a bi-directional charger, a C-contact relay configured to electrically connect the bi-directional charger to either an inlet or an alternating current outlet, and a processor, wherein the processor is configured to:
acquire a first voltage from a first voltmeter provided between the inlet and the C-contact relay, a second voltage from a second voltmeter provided between the C-contact relay and the bi-directional charger, and a third voltage from a third voltmeter provided between the C-contact relay and the alternating current outlet; and
diagnose fusion of the C-contact relay based on the first voltage, the second voltage, and the third voltage.

2. The charge control device according to claim 1, wherein the processor is configured to, when the first voltage, the second voltage, and the third voltage have different values, determine that the C-contact relay is normal and that charging is performable.

3. The charge control device according to claim 2, wherein the processor is configured to, when the first voltage, the second voltage, and the third voltage do not have different values, determine that the C-contact relay is abnormal and prohibit charging from an outside.

4. The charge control device according to claim 3, wherein the processor is configured to, when determination is made that the C-contact relay is abnormal, output an alert indicating that an abnormality has occurred in the C-contact relay.

5. The charge control device according to claim 3, wherein the processor is configured to, when values of the first voltage, the second voltage, and the third voltage are zero, determine that the C-contact relay is in an abnormal state in which the C-contact relay is fused to an infrastructure side, and prohibit the charging from the outside.

6. The charge control device according to claim 3, wherein the processor is configured to, when values of the first voltage, the second voltage, and the third voltage are the same value, determine that the C-contact relay is in an abnormal state in which the C-contact relay is totally fused, and prohibit the charging from the outside.
